(19) United States
(12) Patent Application Publication
(10) Pub. No.: US 2009/0262047 A1
(43) Pub. Date: Oct. 22, 2009

(54) EL display panel and electronic apparatus

(75) Inventors: Junichi Yamashita, Tokyo (JP); Tetsuro Yamamoto, Kanagawa (JP); Katsuhide Uchino, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/379,477

(22) Filed: Feb. 23, 2009

(30) Foreign Application Priority Data
Mar. 23, 2008 (JP) 2008-074774

(51) Int. Cl. G09G 3/30

(52) U.S. Cl. 345/76

(57) ABSTRACT

Disclosed herein is an electroluminescence display panel including pixel circuits corresponding to an active-matrix drive system, the electroluminescence display panel including a structure configured to include first light-emitting areas corresponding to an emission color that is strongest in a characteristic of changing a threshold voltage of a thin film transistor and second light-emitting areas that correspond to another emission color and are each disposed between the first light-emitting areas, wherein a sampling transistor in each of the pixel circuits for driving the second light-emitting areas is disposed in an area corresponding to a range of one fourth to three fourths of a length from a peripheral edge of one of two first light-emitting areas that are adjacent to each other with intermediary of the second light-emitting area of the sampling transistor to a peripheral edge of the other of the two first light-emitting areas.

### CROSS REFERENCES TO RELATED APPLICATIONS

The present invention contains subject matter related to Japanese Patent Application JP 2008-074774 filed in the Japan Patent Office on Mar. 23, 2008, the entire contents of which being incorporated herein by reference.

### BACKGROUND OF THE INVENTION

1. Field of the Invention

The invention to be described in this specification relates to an EL (electroluminescence) display panel whose driving is controlled based on an active-matrix drive system. The invention to be proposed by this specification also has a mode as various kinds of electronic apparatus including an EL display panel.

2. Description of the Related Art

FIG. 1 shows a configuration example of a circuit block used in an active-matrix driven organic EL panel. An organic EL panel 1 shown in FIG. 1 includes a pixel array part 3, and a write control scanner 5, a power supply line scanner 7, and a horizontal selector 9 as drive circuits for the pixel array part 3.

The pixel array part 3 has a matrix pixel structure in which sub-pixels 11 are disposed at the respective intersections of signal lines DTL and write control lines WSL. The sub-pixel 11 is the minimum unit of the pixel structure of one pixel. For example, one pixel as a white unit is formed of an aggregation of three sub-pixels (red (R) pixel, green (G) pixel, blue (B) pixel) based on different organic EL materials, four sub-pixels composed of these sub-pixels and a white (W) pixel, or another sub-pixel group.

FIG. 2 shows a configuration example of a pixel 21. The pixel 21 shown in FIG. 2 is one pixel of displaying, formed as an aggregation of the sub-pixels 11 corresponding to three primary colors. Each of the emission colors is output from a light-emitting area (organic EL element) 23 disposed at substantially the center of the sub-pixel 11.

The sub-pixel 11 in this specification corresponds to an active drive system. Therefore, the sub-pixel 11 is composed of the light-emitting area (organic EL element) 23 and a pixel circuit.

The organic EL element serving as the light-emitting area is a current-driven light-emitting element. Therefore, the luminance grayscales of the organic EL panel are controlled based on the amounts of currents that flow through the organic EL elements corresponding to the respective pixels. A function of the pixel circuit corresponding to the active drive system is to continue this current supply for a certain period.

Referential examples of documents about an organic EL panel display employing the active-matrix drive system include Japanese Patent Laid-opens No. 2003-255856, No. 2003-271095, No. 2004-133240, No. 2004-029791, and No. 2004-093682.

FIG. 3 shows an example of the simplest circuit configuration of the pixel circuit corresponding to the sub-pixel 11. The pixel circuit shown in FIG. 3 includes thin film transistors T1 and T2 and a hold capacitor Cs. Hereinafter, the thin film transistor T1 will be referred to as the “sampling transistor T1,” and the thin film transistor T2 will be referred to as the “drive transistor T2.” In FIG. 2, the position of merely the sampling transistor T1 among the components of the pixel circuit is shown. In FIG. 3, the capacitance of an organic EL element OLED itself is indicated as Coled, and a complementary capacitor therefor is indicated as Csub. The complementary capacitor Csub has the same TFT structure as that of the hold capacitor Cs. Depending on the structure of the pixel circuit, the complementary capacitor Csub is not used in some cases.

The sampling transistor T1 is an N-channel thin film transistor that controls writing of a signal potential Vsig dependent on the grayscale of the corresponding pixel to the hold capacitor Cs. The drive transistor T2 is an N-channel thin film transistor that supplies a drive current Ids to the organic EL element OLED based on a gate-source voltage Vgs dependent on the signal potential Vsig held in the hold capacitor Cs.

The write control scanner 5 is a circuit device that controls the on/off-operation of the sampling transistor T1. The power supply line scanner 7 is a circuit device that drives a power supply line DSL with a higher potential Vcc and a lower potential Vss. The horizontal selector 9 is a circuit device that drives the signal line DTL with the signal potential Vsig corresponding to pixel data Din and a reference potential Vofs for threshold voltage correction.

During a light-emission period, the power supply line DSL is driven with the higher potential Vcc and the drive current Ids is supplied from the power supply line DSL via the drive transistor T2 to the organic EL element OLED. The drive transistor T2 typically operates in the saturation region during the light-emission period. Specifically, the drive transistor T2 operates as a constant current source that supplies the drive current Ids having the magnitude dependent on the signal potential Vsig to the organic EL element OLED.

This drive current Ids is represented by the following equation.

Ids=k·μ·(Vgs−Vth)² (Equation 1)

In Equation 1, μ denotes the mobility of the majority carrier in the drive transistor T2. Vth denotes the threshold voltage of the drive transistor T2. k is a coefficient represented as (W/L)·Cox/2. W denotes the channel width, L denotes the channel length, and Cox denotes the gate capacitance per unit area.

For forming the pixel circuit 11, a low-temperature poly-silicon process and an amorphous silicon process as well as a high-temperature poly-silicon process can be used. However, characteristic variation in the threshold voltage Vth and the mobility μ easily arises in a thin film transistor formed by using a low-temperature poly-silicon process or an amorphous silicon process.

In particular, the characteristic variation of the drive transistor T2 directly affects the magnitude of the drive current Ids. Specifically, even with the same signal potential Vsig, difference arises in the luminance grayscale of the organic EL element. The luminance difference larger than a certain degree is visually recognized on the screen.

To address this problem, techniques for correction relating to the threshold voltage Vth and the mobility μ have been proposed for this kind of pixel circuit in related arts.

FIGS. 4A to 4E show an example of drive operation with the characteristic correction functions proposed by the present assignee. FIGS. 4A to 4E show an example of the drive operation on one of the same number of horizontal lines as the vertical resolution, in the pixel array part 3. A one-frame period is composed of a non-light-emission period and a light-emission period, and the above-described characteristic correction operation is carried out in the non-light-emission period.

FIG. 4A is a waveform diagram of a certain signal line DTL. FIG. 4B is a waveform diagram of the write control line WSL. FIG. 4C is a waveform diagram of the power supply line DSL. FIG. 4D is a waveform diagram of the gate potential Vg of the drive transistor T2. FIG. 4E is a waveform diagram of the source potential Vs of the drive transistor T2.

The drive operation shown in FIGS. 4A to 4E will be simply described below. In the drive operation shown in FIGS. 4A to 4E, the potential of the power supply line DSL is switched to the lower potential Vss at the start timing of the non-light-emission period. In response to this, the source potential Vs of the drive transistor T2 decreases to reach the lower potential Vss. The light emission of the organic EL element OLED is automatically stopped at the timing when the source potential Vs becomes lower than a potential Vcat+Vthel, which is the sum of the threshold voltage Vthel of the organic EL element OLED and the cathode potential Vcat thereof.

In this operation, the gate electrode of the drive transistor T2 is in the open state and therefore the gate potential Vg also decreases in linkage with the decrease in the source potential Vs.

The threshold correction operation for the drive transistor T2 will be described below. The threshold correction operation for the drive transistor T2 starts in response to switching of the potential of the power supply line DSL to the higher potential Vcc. The potential of the power supply line DSL will be continuously kept at the higher potential Vcc until the end timing of the subsequent light-emission period.

Before the switching of the potential of the power supply line DSL to the higher potential Vcc, the sampling transistor T1 is switched to the on-state and thereby the gate potential Vg of the drive transistor T2 is fixed at the offset potential Vofs. Due to this operation, the gate-source voltage Vgs of the drive transistor T2 is preset to a voltage Vofs−Vss higher than the threshold voltage Vth thereof.

Upon the switching of the potential of the power supply line DSL to the higher potential Vcc in this preset state, current flows through the drive transistor T2 and the source potential Vs rises up as shown in FIG. 5.

This current flow charges the hold capacitor Cs and the parasitic capacitor of the organic EL element OLED. Along with the charging of the parasitic capacitor, the source potential Vs of the drive transistor T2 rises up. The source potential Vs reaches Vofs−Vth in due course. At this timing, the drive transistor T2 is automatically cut off. This is equivalent to the completion of the threshold correction. At this time, the organic EL element OLED does not emit light because the condition that the potential Vofs−Vth is lower than the potential Vcat+Vthel is satisfied.

Thereafter, the sampling transistor T1 is turned off temporarily. Thereafter, the sampling transistor T1 is turned on again after the signal potential Vsig has been applied to the signal line DTL. Due to this operation, the gate-source voltage Vgs of the drive transistor T2 becomes higher than the threshold voltage Vth again, and current having the magnitude dependent on the signal potential Vsig starts to flow. This is writing and mobility correction operation.

Also in this operation, the current flow charges the hold capacitor Cs and the parasitic capacitor of the organic EL element OLED. The current flowing through the drive transistor T2 depends on the mobility μ. Specifically, larger current flows through the drive transistor T2 having higher mobility μ, and smaller current flows through the drive transistor T2 having lower mobility μ.

As a result, the degree of the increase in the source potential Vs of the drive transistor T2 having higher mobility μ is higher than that of the increase in the source potential Vs of the drive transistor T2 having lower mobility μ. FIG. 6 shows difference in the change in the source potential Vs of the drive transistor T2 attributed to difference in the mobility μ.

At the end of this mobility correction operation, the sampling transistor T1 is turned off, and a drive current Ids' of the drive transistor T2 starts to flow to the organic EL element OLED. This starts the new light-emission period of the organic EL element OLED.

The purpose of the correction operation carried out through the above-described drive operation is to correct characteristic variation of the drive transistor T2. That is, correction operation for characteristic variation of the sampling transistor T1 is not designed. One of the reasons therefor is that the sampling transistor T1 is switch-driven and therefore the influence of the characteristic variation thereof is small.

However, change in the threshold voltage Vth of the sampling transistor T1 (i.e. change in the on-period thereof) causes change in the operating point of the mobility correction for the drive transistor T2 and thus affects the accuracy of the mobility correction. That is, change in the threshold voltage Vth of the sampling transistor T1 causes change in the luminance level.

One of the factors in the change in the threshold voltage Vth is a reverse (negative) bias in the light-emission period. FIG. 7 shows the potential state in the light-emission period. The potential state of FIG. 7 corresponds to the case in which the signal potential Vsig has the potential value corresponding to the white level. The anode potential Vel of the organic EL element OLED (the source potential Vs of the drive transistor T2) is 5 V, and the gate potential Vg of the drive transistor T2 is 10 V.

On the other hand, the gate potential Vg of the sampling transistor T1 is −3 V, and therefore the sampling transistor T1 is continuously reverse (negatively) biased. This bias state acts to decrease the threshold voltage Vth of the sampling transistor T1. In addition, this change in the threshold voltage Vth is amplified due to the incidence of scattered light in the panel on the sampling transistor T1.

FIG. 8 shows a sectional structural example of an organic EL panel having a top-emission structure. The top-emission structure refers to a panel structure of the type in which light is output from the sealing substrate side. In FIG. 8, a glass substrate 31 is equivalent to the sealing substrate. It is also possible to use a plastic film or another transparent material as the sealing substrate.

A sealing material 33 having high transparency is applied on the lower surface of the sealing substrate 31. Under the sealing material 33, a cathode electrode 35, an organic layer 37, and an anode electrode 39 that form the organic EL element OLED are sequentially formed. The cathode electrode 35 is composed of an optically-transparent material. The anode electrode 39 is composed of a metal material.

In the structure of FIG. 8, an auxiliary interconnect 41 is disposed in the gap between the anode electrodes 39. The auxiliary interconnect 41 supplies a cathode potential to the cathode electrode 35 and is composed of the same metal material as that of the anode electrode 39. This auxiliary interconnect 41 is frequently used if the panel size is large, and is not used if the panel size is small in many cases. A pixel circuit is formed below the organic EL element OLED. An example of a bottom-gate thin film transistor is shown in FIG. 8.

In the structure of FIG. 8, the pixel circuit includes a source electrode 43, a drain electrode 45, an interlayer film 47, a poly-silicon layer (channel layer) 49, a gate oxide film 51, and a gate electrode 53. This pixel circuit is formed on a surface of a glass substrate 55 as a substrate over which drive elements are formed (so-called circuit substrate). An interlayer film 57 is formed between the glass substrate 55 and the anode electrode 39, which is the lower electrode layer of the organic EL element OLED.

A description will be made below about internal scattered light indicated by the heavy line with the arrowhead. Originally light generated by the organic EL element OLED is output from the inside of the panel to the outside of the sealing substrate.

However, part of the scattered light is often repeatedly reflected inside the panel. As a result, the scattered light is possibly incident on the channel region of the sampling transistor T1 of an adjacent pixel as shown by the arrowhead in FIG. 8.

FIG. 9 shows one example of the result of measurement of characteristic change in the threshold voltage Vth, obtained through the continuation of the incidence of internal scattered light and application of a reverse (negative) bias.

As shown in FIG. 9, the threshold voltage Vth gradually decreases as the stress time becomes longer, and the decrease amount of the threshold voltage Vth becomes particularly large if the stress time has surpassed around 1000 seconds.

In the experiment performed by the present inventors, the decrease effect of the threshold voltage Vth was observed with blue internal scattered light having a short wavelength, whereas the decrease effect of the threshold voltage Vth was not observed or was very small with green and red internal scattered light having a relatively-long wavelength.

If the threshold voltage Vth of the sampling transistor T1 is decreased, the on-period of the sampling transistor T1 becomes longer as shown in FIG. 10.

In FIG. 10, the transient characteristic is emphatically shown. The extension of the on-period of the sampling transistor T1 leads to increase in the mobility correction time. That is, it leads to change in the operating point of the mobility correction.

The mobility correction operation involves increase in the source potential Vs of the drive transistor T2. Therefore, the extension of the correction time acts to correspondingly decrease the gate-source voltage Vgs.

The magnitude of the drive current Ids after the mobility correction can be represented by the following equation.

Ids=k·μ·{(Vsig−Vofs)/[1+(Vsig−Vofs)·k·μ·t/C]}² (Equation 2)

As is apparent also from Equation 2, longer correction time t provides smaller drive current Ids. The capacitance C in Equation 2 is equal to the total sum of the capacitance of the hold capacitor Cs, the capacitance of the complementary capacitor Csub, and the capacitance Coled of the organic EL element OLED itself (C=Cs+Csub+Coled).

That is, when the change in the threshold voltage Vth of the sampling transistor T1 is large, the drive current Ids becomes smaller than the originally-designed current eventually. Therefore, the present inventors think that a technique to minimize the influence of internal scattered light, which accelerates the change in the threshold voltage Vth, is necessary.

### SUMMARY OF THE INVENTION

Thus, the present inventors propose to employ the following structure for an EL display panel having a pixel structure corresponding to an active-matrix drive system.

Specifically, the structure includes first light-emitting areas corresponding to an emission color that is strongest in a characteristic of changing the threshold voltage of a thin film transistor and second light-emitting areas that correspond to another emission color and are each disposed between the first light-emitting areas. Furthermore, in this structure, a sampling transistor in each of the pixel circuits for driving the second light-emitting areas is disposed in the area corresponding to the range of one fourth to three fourths of the length from the peripheral edge of one of two first light-emitting areas that are adjacent to each other with the intermediary of the second light-emitting area of this sampling transistor to the peripheral edge of the other of these two first light-emitting areas.

In addition, if the first light-emitting areas are adjacent to each other in the panel, a sampling transistor in each of the pixel circuits for driving the first light-emitting areas is disposed in the area corresponding to the range of one fourth to three fourths of the length of the first light-emitting area of this sampling transistor along the direction along which the first light-emitting areas are adjacent to each other.

The relationship between the first light-emitting area and the emission color thereof depends on the material used for the light-emitting element. For example, a light-emitting area corresponding to blue light or white light is defined as the first light-emitting area.

Moreover, the present inventors propose electronic apparatus including the EL display panel having the above-described structure.

The electronic apparatus includes the EL display panel, a system controller that controls the operation of the entire system, and an operation input unit that accepts an operation input to the system controller.

In a color panel, light-emitting areas corresponding to the respective colors repeatedly appear in accordance with the prescribed layout.

Therefore, to each pixel (including the light-emitting area and the peripheral gap area), internal scattered light from the adjacent pixels on all sides comes.

However, in the layout structure proposed by the present inventors, at least one fourth of the distance between adjacent two first light-emitting areas is ensured as the distance from the peripheral edge of the light-emitting area corresponding to the emission color that is the strongest in the characteristic of changing the threshold voltage (first light-emitting area) to the sampling transistor for driving the light-emitting area corresponding to another emission color (second light-emitting area).

This means that the light amount of internal scattered light incident on the channel layer of the sampling transistor can be decreased. That is, the influence of the internal scattered light can be minimized although it may be difficult to completely eliminate the influence. Thus, the operating point in mobility correction can be stabilized.

### BRIEF DESCRIPTION OF THE DRAWINGS

FIG. 1 is a diagram for explaining the functional block configuration of an organic EL panel;

FIG. 2 is a diagram showing a pixel structure example;

FIG. 3 is a diagram for explaining the connection relationship between a pixel circuit and drive circuits;

FIGS. 4A to 4E are a diagram showing a drive operation example of the pixel circuit shown in FIG. 3;

FIG. 5 is a diagram for explaining change in the source potential of a drive transistor in threshold correction operation;

FIG. 6 is a diagram for explaining change in the source potential of the drive transistor in mobility correction operation;

FIG. 7 is a diagram for explaining the potential relationship in the pixel circuit in a light-emission period;

FIG. 8 is a diagram for explaining a propagation path of internal scattered light;

FIG. 9 is a diagram for explaining change in the threshold voltage of a sampling transistor;

FIG. 10 is a diagram for explaining the relationship between change in the threshold voltage and the mobility correction time;

FIG. 11 is a diagram showing an appearance configuration example of an organic EL panel;

FIG. 12 is a diagram for explaining the connection relationship between a pixel circuit and drive circuits;

FIG. 13 is a diagram showing a configuration example of a pixel circuit according to a first form example of the present invention;

FIG. 14 is a diagram showing a layout example of sampling transistors T1 employed in a pixel circuit having a related-art structure;

FIG. 15 is a diagram showing a layout example of the sampling transistors T1 employed in the pixel circuit according to the first form example;

FIG. 16 is a diagram showing the position range of the sampling transistor T1 employed in the pixel circuit according to the first form example;

FIG. 17 is a diagram for explaining the relationship between the grayscale luminance and the optimum mobility correction time;

FIG. 18 is a diagram for explaining the signal waveform of a write control signal used for optimization of the mobility correction time dependent on the grayscale luminance;

FIG. 19 is a diagram for explaining the circuit configuration of a write control scanner proposed in the form example;

FIG. 20 is a diagram for explaining a waveform example of a supply voltage pulse proposed in the form example;

FIG. 21 is a diagram for explaining circuitry for generating the supply voltage pulse;

FIG. 22 is a diagram for explaining an internal configuration example of a drive power generator;

FIGS. 23A and 23B are diagrams for explaining a technical effect obtained when a technique of optimizing the arrangement positions of the sampling transistors T1 is combined with a drive technique with use of the write control signal shown in FIG. 18;

FIG. 24 is a diagram showing another layout example of the sampling transistors T1;

FIG. 25 is a diagram showing another layout example of the sampling transistors T1;

FIG. 26 is a diagram showing another layout example of the sampling transistors T1;

FIG. 27 is a diagram showing a conceptual configuration example of electronic apparatus;

FIG. 28 is a diagram showing a commercial product example of the electronic apparatus;

FIGS. 29A and 29B are diagrams showing a commercial product example of the electronic apparatus;

FIG. 30 is a diagram showing a commercial product example of the electronic apparatus;

FIGS. 31A and 31B are diagrams showing a commercial product example of the electronic apparatus; and

FIG. 32 is a diagram showing a commercial product example of the electronic apparatus.

### DETAILED DESCRIPTION OF THE PREFERRED EMBODIMENT

The following description will deal with an example in which an embodiment of the present invention is applied to an active-matrix driven organic EL panel.

Well-known or publicly-known techniques in the related-art technical field are applied to part that is not particularly illustrated or described in the present specification. It should be noted that the form examples to be described below is merely one embodiment example of the present invention and the present invention is not limited thereto.

### (A) Appearance Configuration

In this specification, e.g. one obtained by mounting drive circuits manufactured as application-specific ICs on a substrate on which a pixel array part is formed not merely a display panel obtained by forming a pixel array part and drive circuits (such as a write control scanner and a power supply line scanner) on the same substrate by using the same semiconductor process but also is referred to as an organic EL panel.

FIG. 11 shows an appearance configuration example of an organic EL panel. An organic EL panel 61 has a structure obtained by bonding a counter substrate 65 to the formation area of a pixel array part of a support substrate 63.

The support substrate 63 is composed of glass, plastic, or another base material. In the case of a top-emission structure, a pixel circuit is formed on a surface of the support substrate 63. That is, the support substrate 63 is equivalent to the circuit substrate. In the case of a bottom-emission structure, an organic EL element is formed on the surface of the support substrate 63. That is, the support substrate 63 is equivalent to the sealing substrate.

The base of the counter substrate 65 is also composed of glass, plastic, or another transparent material. The counter substrate 65 is the component that seals the surface of the support substrate 63 with the intermediary of a sealing material. In the case of a top-emission structure, the counter substrate 65 is equivalent to the sealing substrate. In the case of a bottom-emission structure, the counter substrate 65 is equivalent to the circuit substrate.

For the organic EL panel 61, a flexible printed circuit (FPC) 67 for input of external signals and drive power is provided.

### (B) First Form Example

### (B-1) System Configuration

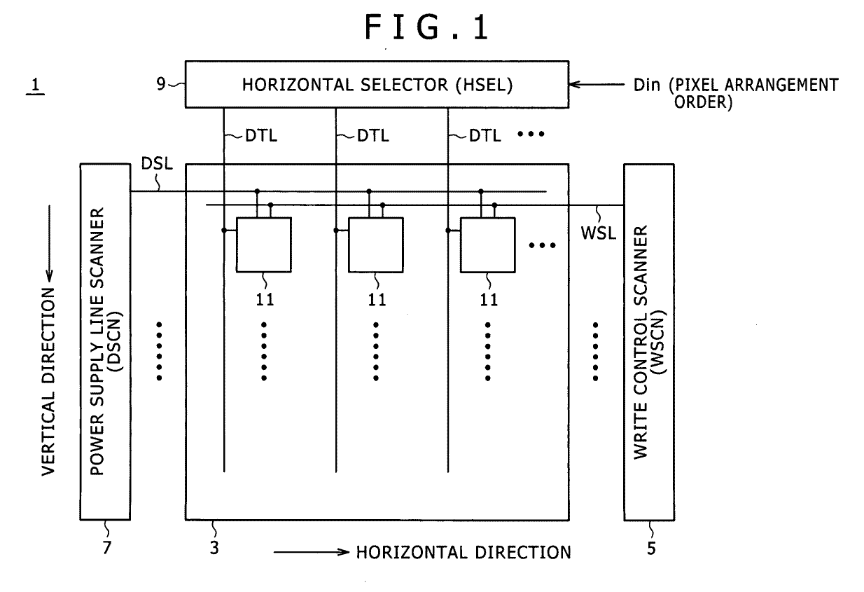

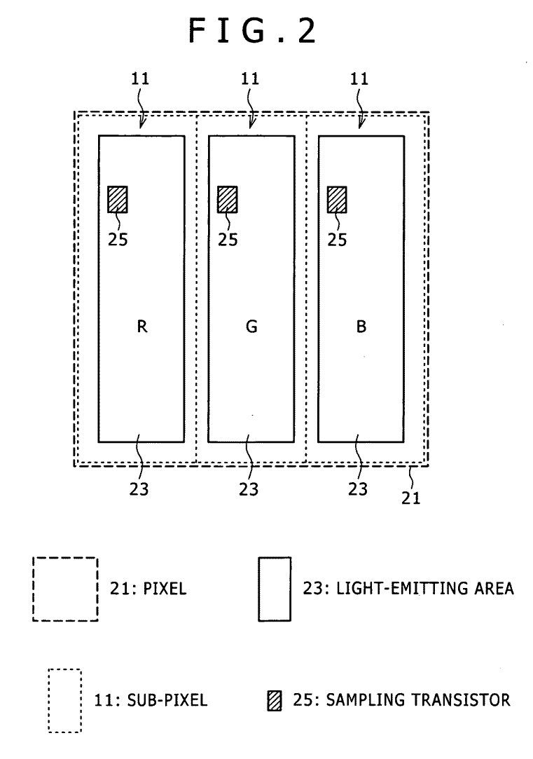

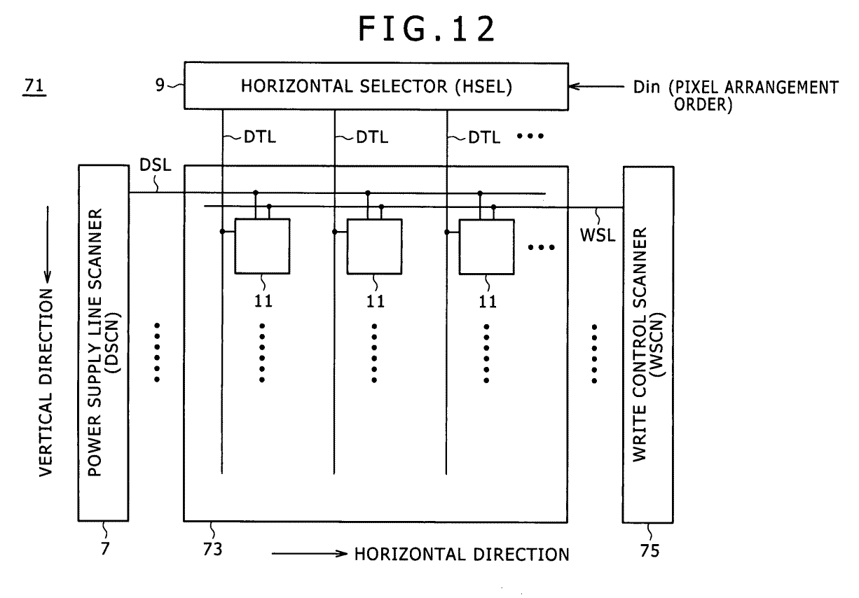

FIG. 12 shows a system configuration example of an organic EL panel 71 according to a form example of the present invention. The same components in FIG. 12 as those in FIG. 1 are given the same numerals.

The organic EL panel 71 shown in FIG. 12 includes a pixel array part 73, and a write control scanner 75, a power supply line scanner 7, and a horizontal selector 9 as drive circuits for the pixel array part 73.

### (1) Configuration of Pixel Array Part

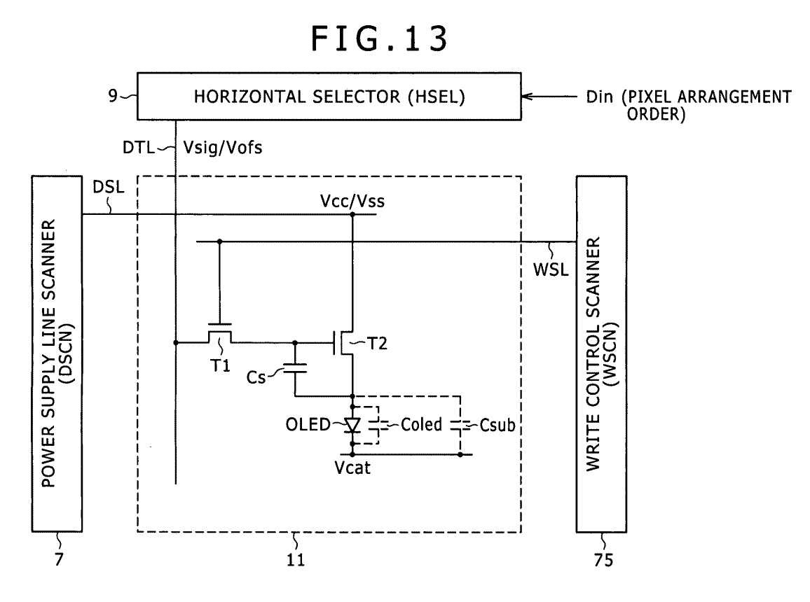

In the pixel array part 73, sub-pixels 11 corresponding to red (R) pixels, green (G) pixels, and blue (B) pixels are arranged in a matrix. FIG. 13 shows the connection relationship between the pixel circuit corresponding to the sub-pixel 11 and the above-described respective drive circuits.

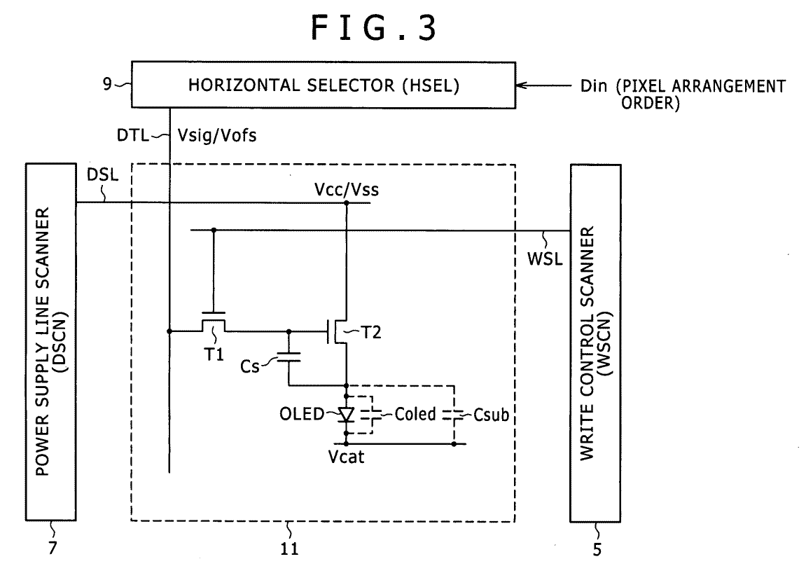

The electric configuration of the pixel circuit in this form example is the same as that shown in FIG. 3. Specifically, this pixel circuit includes a sampling transistor T1, a drive transistor T2, and a hold capacitor Cs. The gate electrode of the sampling transistor T1 is connected to a write control line WSL, and one main electrode of the drive transistor T2 is connected to a power supply line DSL.

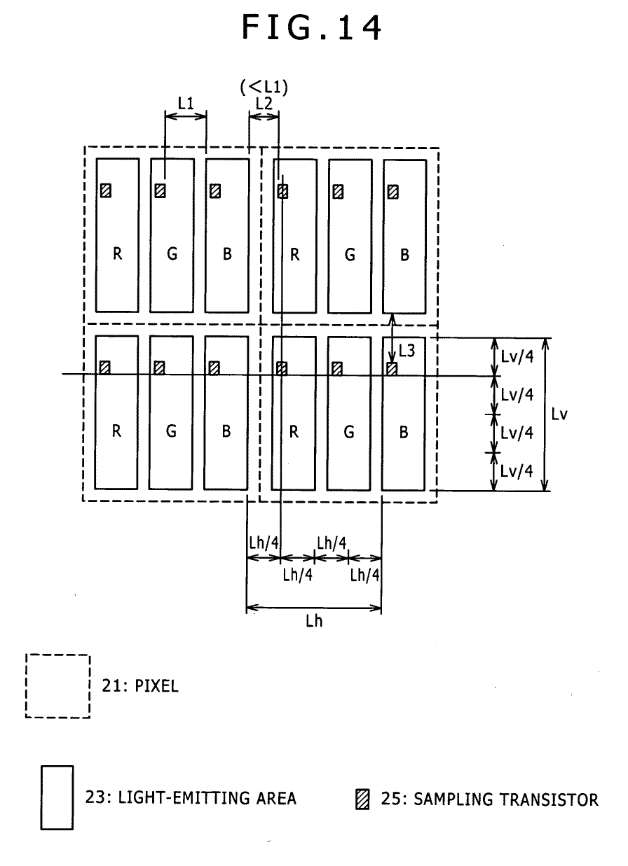

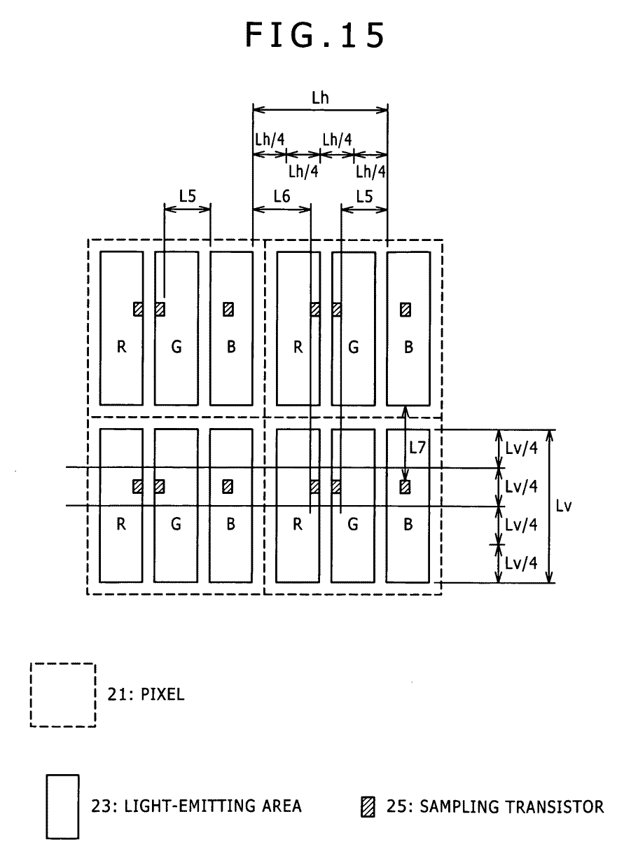

The difference between the organic EL panel 1 shown in FIG. 1 and the organic EL panel 71 shown in FIG. 12 is the arrangement position of the sampling transistor T1 included in the pixel circuit for driving the sub-pixel 11. FIG. 14 shows the arrangement positions of the sampling transistors T1 employed in the organic EL panel 1 (related art). FIG. 15 shows the arrangement positions of the sampling transistors T1 employed in the organic EL panel 71 (form example).

As shown in FIG. 14, the pixel circuit of the related-art structure employs a uniform layout structure irrespective of the emission color. Specifically, each sampling transistor T1 is disposed at the same position in the pixel area. Generally, the position thereof is biased toward one of four corners of a light-emitting area 23 having a rectangular shape. In the structure of FIG. 14, each sampling transistor T1 is disposed at a position near the upper left corner.

However, this element arrangement involves a problem that the distances between the peripheral edge of the light source of blue internal scattered light, which changes the threshold voltage of the sampling transistor T1, (i.e. the peripheral edge of the light-emitting area of the B pixel) and the sampling transistors T1 corresponding to the other colors tend to be short. That is, this element arrangement involves a problem that the distances between the peripheral edge of the light-emitting area of the B pixel and the sampling transistors T1 of the R and G pixels adjacent to this B pixel tend to be short.

In the pixel arrangement of FIG. 14, a distance L1 between the sampling transistor T1 of the G pixel and the peripheral edge of the light-emitting area of the closest B pixel is larger than one fourth of a distance Lh between the peripheral edges of the light-emitting areas of two B pixels. However, a distance L2 between the sampling transistor T1 of the R pixel and the peripheral edge of the light-emitting area of the closest B pixel is smaller than one fourth of the distance Lh between the peripheral edges of the light-emitting areas of two B pixels.

That is, the sampling transistor T1 of the R pixel is closer to the light-emitting area 23 of the B pixel and more susceptible to the influence of blue internal scattered light than the sampling transistor T1 of the G pixel. This means that larger change will arise in the long term in the threshold voltage Vth of the sampling transistor T1 of the R pixel compared with the threshold voltages Vth of the sampling transistors T1 of the other colors.

Furthermore, in the structure of FIG. 14, the B pixels are adjacent to each other along the vertical direction because the same pixel arrangement is employed on each horizontal line. Therefore, if the sampling transistor T1 is disposed close to a corner of the light-emitting area 23, a distance L3 between the sampling transistor T1 of the B pixel and the peripheral edge of the light-emitting area of another B pixel also tends to be short. If the distance L3 is short, the change in the threshold voltage Vth of the sampling transistor T1 of the B pixel over time tends to be large as in the R pixel.

In contrast, in the pixel circuit proposed by the present inventors, as shown in FIG. 15, the sampling transistor T1 for driving the R pixel and the sampling transistor T1 for driving the G pixel are disposed at positions remotest from the B pixel adjacent to the respective pixel areas.

Specifically, the sampling transistor T1 for driving the R pixel is disposed on the right side of the pixel area (in FIG. 15, on the right side of the light-emitting area 23), and the sampling transistor T1 for driving the G pixel is disposed on the left side of the pixel area (in FIG. 15, on the left side of the light-emitting area 23). In this manner, the positions of the sampling transistors T1 in the pixel area in the R pixel and the G pixel are in a horizontally-symmetrical relationship.

In the pixel arrangement of FIG. 15, a distance L5 (>L1) between the sampling transistor T1 of the G pixel and the peripheral edge of the light-emitting area of the closest B pixel and a distance L6 (>L2) between the sampling transistor T1 of the R pixel and the peripheral edge of the light-emitting area of the closest B pixel are larger than one fourth of the distance Lh between the peripheral edges of the light-emitting areas of two B pixels.

Naturally, if the distance from the peripheral edge of the light-emitting area of the B pixel becomes larger, the light amount of internal scattered light incident on the channel region of the sampling transistor T1 is decreased. Therefore, change in the threshold voltage Vth of the sampling transistors T1 of the R pixel and the G pixel can be made smaller in the pixel arrangement shown in FIG. 15 than in that shown in FIG. 14.

Incidentally, in the structure of FIG. 15, the distance between the sampling transistor T1 of the R pixel and the peripheral edge of the light-emitting area of the G pixel and the distance between the sampling transistor T1 of the G pixel and the peripheral edge of the light-emitting area of the R pixel are smaller than those in the structure of FIG. 14.

However, change in the threshold voltage Vth of the sampling transistor T1 attributed to internal scattered light of red light and green light, which have low wave energy, is very small. Thus, the influence of internal scattered light other than blue light can be ignored.

Moreover, in the structure of FIG. 15, the sampling transistor T1 of the B pixel adjacent along the vertical direction is disposed at a position that is separated from the peripheral edge of the light-emitting area toward the inside by a distance equal to or larger than one fourth of a vertical length Lv of the light-emitting area.

Therefore, a distance L7 between the sampling transistor T1 for driving the B pixel and the peripheral edge of the light-emitting area of another B pixel adjacent thereto along the vertical direction is larger than the distance L3 in the structure of FIG. 14. Consequently, by employing the pixel structure shown in FIG. 15, change in the threshold voltage Vth of the sampling transistor T1 for driving the B pixel can be made smaller than that in the pixel structure shown in FIG. 14.

In the above description, distances along the horizontal direction are treated as the distances between the sampling transistors T1 corresponding to the R pixel and the G pixel and the peripheral edge of the light-emitting area of the B pixel. This is because the gap between the sub-pixels is smaller along the horizontal direction (the lateral direction in the drawing) than along the vertical direction (the upward/downward direction in the drawing).

That is, as the distance between the sampling transistor T1 and the adjacent B pixel, the distance along the horizontal direction is the smallest among distances along all directions. Therefore, it is desired that, depending on the shape of the sub-pixels and the pixel arrangement, the positions of the sampling transistors T1 corresponding to the R pixel and the G pixel are determined with focus on the vertical direction and the diagonal direction of the screen.

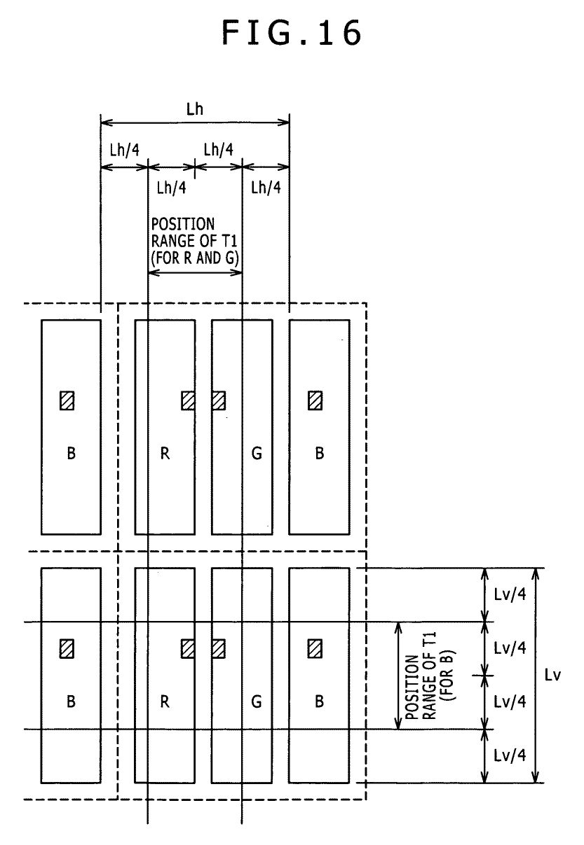

According to the actual measurement results by the present inventors, two conditions can be defined as shown in FIG. 16 as the boundary values of recognition of the effect of reduction in change in the threshold voltage Vth of the sampling transistor T1 due to blue internal scattered light.

One of the conditions is for the case in which a pixel of another color exists between two B pixels, and the other is for the case in which a pixel of another color does not exist between two B pixels.

The former offers the condition of the position of the sampling transistors T1 for driving the R pixel and the G pixel. The latter offers the condition of the position of the sampling transistor T1 for driving the B pixel.

In the former condition, the sampling transistor T1 is disposed in the area corresponding to the range of one fourth to three fourths of the length Lh from the peripheral edge of the light-emitting area of one of two B pixels adjacent to each other with the intermediary of the light-emitting area of this sampling transistor T1 to the peripheral edge of the light-emitting area of the other of these two B pixels. In the example of FIG. 15 (FIG. 16), the sampling transistors T1 are disposed at positions remotest from the adjacent B pixels, in the light-emitting areas 23 of the respective pixels.

In the latter condition, the sampling transistor T1 is disposed in the area corresponding to the range of one fourth to three fourths of the length Lv between the shorter sides of the light-emitting area of this sampling transistor T1 (i.e. the length of the light-emitting area along the vertical direction). For the sampling transistor T1 of the B pixel, the position remotest from the adjacent B pixels, in the light-emitting area 23 of this pixel, is the center of this light-emitting area. In the example of FIG. 15 (FIG. 16), the sampling transistors T1 are disposed at positions that are slightly offset from the center.

### (2) Configuration of Write Control Scanner

The write control scanner 75 employed in the organic EL panel 71 according to this form example will be described below. The new function of this write control scanner 75 is a technique for optimizing the mobility correction time depending on the grayscale luminance.

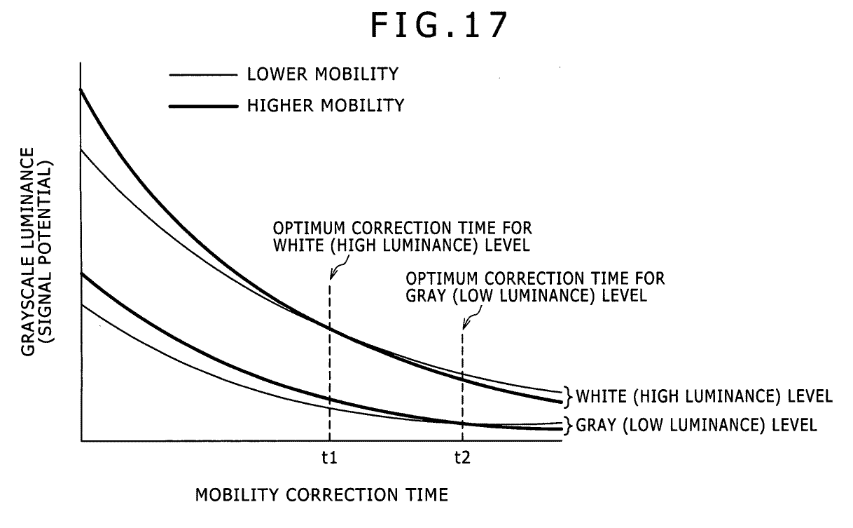

FIG. 17 shows the relationship between the grayscale luminance and the corresponding optimum mobility correction time. The abscissa of FIG. 17 indicates the mobility correction time, and the ordinate indicates the grayscale luminance (signal potential Vsig).

As shown in FIG. 17, for high luminance (white level), the luminance level by the drive transistor T2 having higher mobility μ and that by the drive transistor T2 having lower mobility μ are the same at the timing when the mobility correction time is t1. Therefore, it is desired that the mobility correction time for the high-luminance pixel is t1.

On the other hand, for low luminance (gray level), the luminance level by the drive transistor T2 having higher mobility μ and that by the drive transistor T2 having lower mobility μ are the same at the timing when the mobility correction time is t2. Therefore, it is desired that the mobility correction time for the low-luminance pixel is t2.

Therefore, if a drive system in which the mobility correction time is fixed is employed, deficiency and excess of the mobility correction time will arise in the pixel circuits other than that corresponding to the specific luminance level. The deficiency and excess will be visually recognized as luminance unevenness and streaks in the worst case.

To address this problem, the write control scanner 75 is provided with a function to automatically adjust the mobility correction times of the respective pixel circuits depending on the luminance levels of the respective pixels.

Specifically, a drive function is employed that is so controlled that the mobility correction time is automatically shortened in the pixel circuit corresponding to a high-luminance level and the mobility correction time is automatically extended in the pixel circuit corresponding to a low-luminance level.

The mobility correction time is given as the on-operation time of the sampling transistor T1.

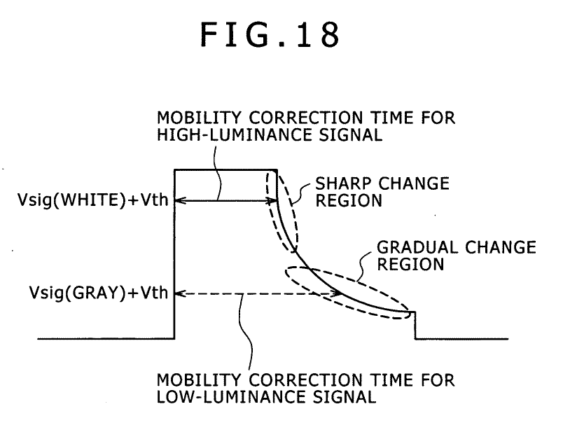

Therefore, for this form example, the write control scanner 75 is proposed that has a function capable of designing a waveform like that shown in FIG. 18 as the waveform of the write control signal for the sampling transistor T1 corresponding to the mobility correction period. The write control signal shown in FIG. 18 has a waveform region in which the potential sharply decreases and a waveform region in which the potential gradually decreases.

Due to adoption of this write control signal, in a high-luminance pixel, the gate-source voltage Vgs of the sampling transistor T1 becomes lower than the threshold voltage Vth thereof (the sampling transistor T1 is automatically cut off) in the region in which the waveform sharply changes. On the other hand, in a low-luminance pixel, the gate-source voltage Vgs of the sampling transistor T1 becomes lower than the threshold voltage Vth thereof (the sampling transistor T1 is automatically cut off) in the region in which the waveform gradually changes.

This means that the mobility correction times of the respective pixels are automatically adjusted depending on the magnitude of the signal potential Vsig and the optimum mobility correction operation is ensured irrespective of the difference in the signal potential Vsig.

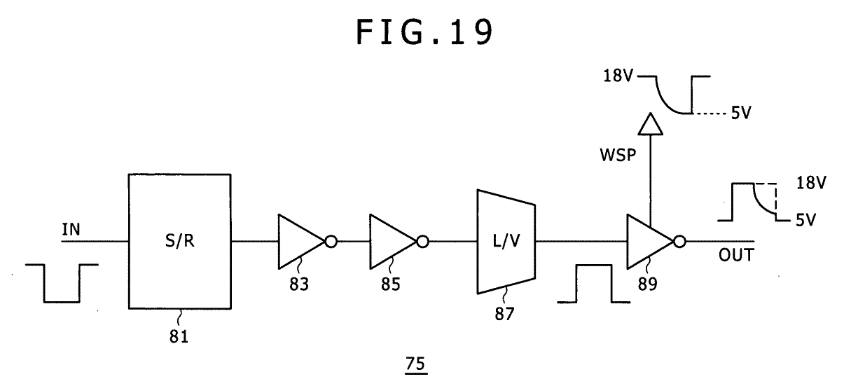

FIG. 19 shows a partial configuration example of the write control scanner 75 that generates the above-described write control signal. The configuration shown in FIG. 19 corresponds to one horizontal line. Therefore, the same number of circuits having the configuration shown in FIG. 19 as the vertical resolution are disposed along the vertical direction of the screen.

Hereinafter, this partial circuit will also be referred to as the write control scanner 75. The write control scanner 75 includes a shift register 81, a buffer circuit composed of two-stage inverter circuits 83 and 85, and an output buffer circuit composed of a level shifter 87 and a one-stage inverter circuit 89.

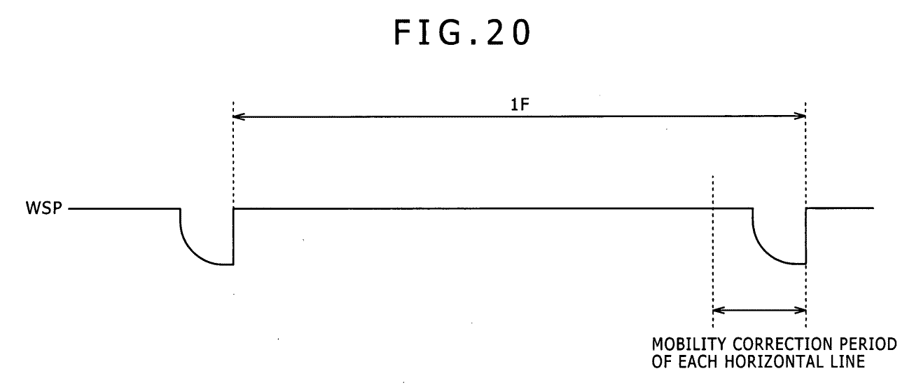

This configuration itself is typical. A characteristic of this configuration is that the waveform level of a supply voltage pulse WSP supplied to the inverter circuit 89 decreases with the characteristic shown in FIG. 20.

Naturally, this decrease in the waveform level should be carried out with phase synchronization in the mobility correction period of each horizontal line as shown in FIG. 20.

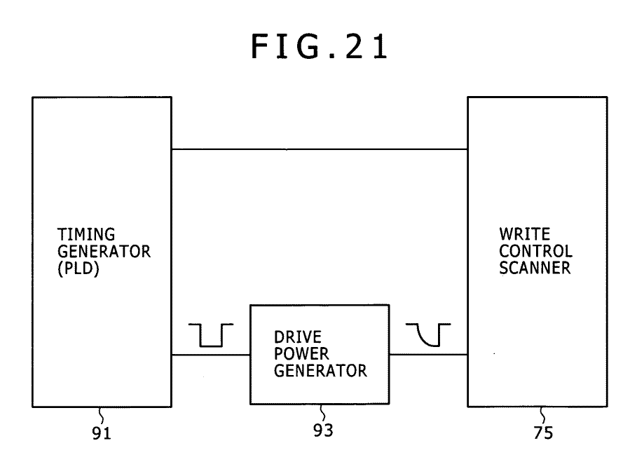

FIG. 21 shows the configuration of a circuit device that generates the supply voltage pulse WSP to be supplied to the write control scanner 75.

The supply voltage pulse WSP is generated by a timing generator 91 and a drive power generator 93. The timing generator 91 is a circuit device that supplies a drive pulse (rectangular wave) to the power supply line scanner 7 and the horizontal scanner 9 as well as to the write control scanner 75. The timing of the falling-down of the drive pulse is set to a timing delayed by a predetermined time with respect to the start timing of the mobility correction.

The drive power generator 93 is a circuit device that generates the drive voltage pulse WSP (FIG. 20) whose falling waveform is bent in two stages, based on a drive pulse having a rectangular waveform.

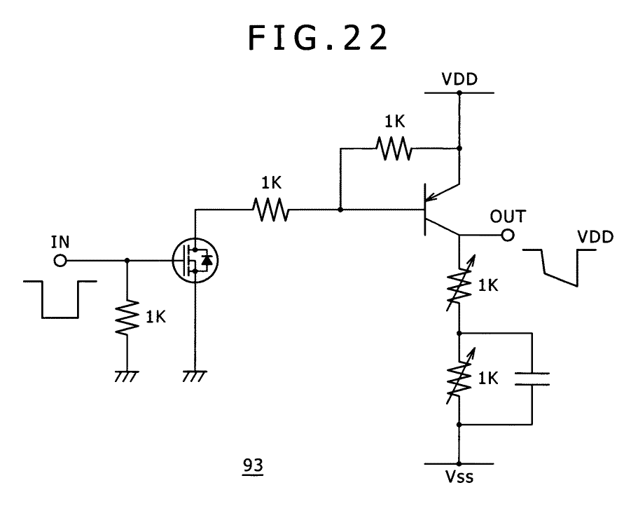

FIG. 22 shows a circuit example of the drive power generator 93. The drive power generator 93 shown in FIG. 22 includes two transistors, one capacitor, three fixed resistors, and two variable resistors.

The drive power generator 93 subjects a drive pulse to analog processing to thereby generate the supply voltage pulse WSP whose falling waveform is bent in two stages. Specifically, it generates the supply voltage pulse WSP with a waveform in which the inclination angle of the first falling-down is large and that of the second falling-down is small.

### (B-2) Drive Operation and Advantageous Effects

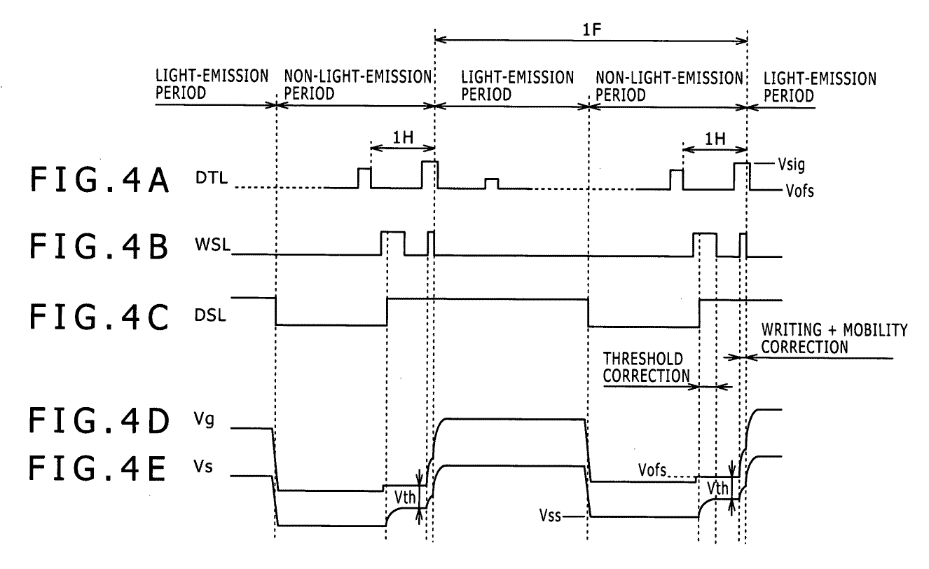

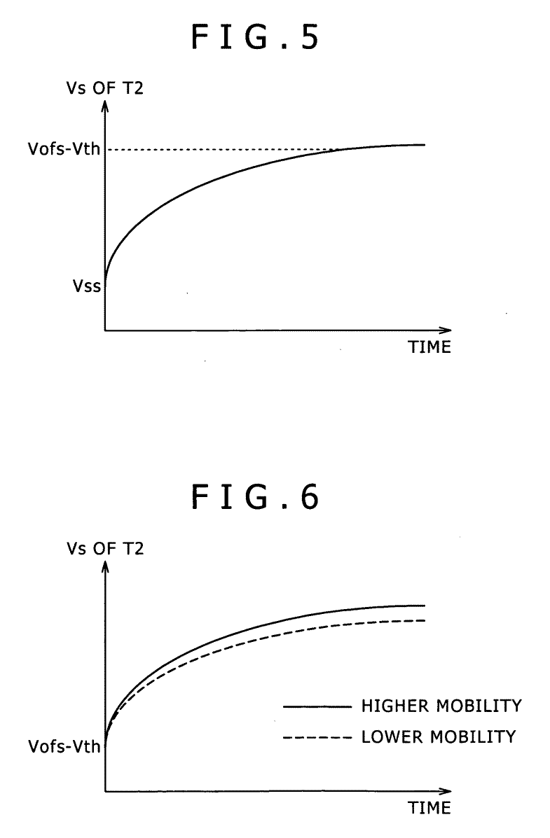

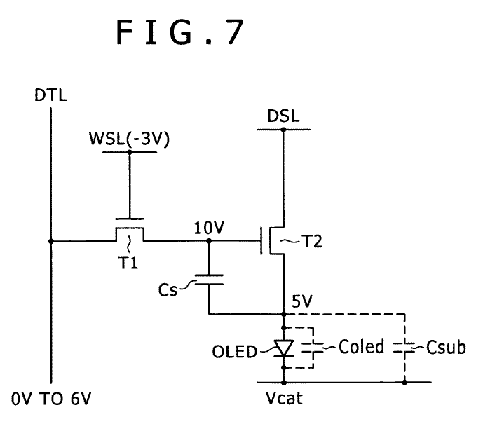

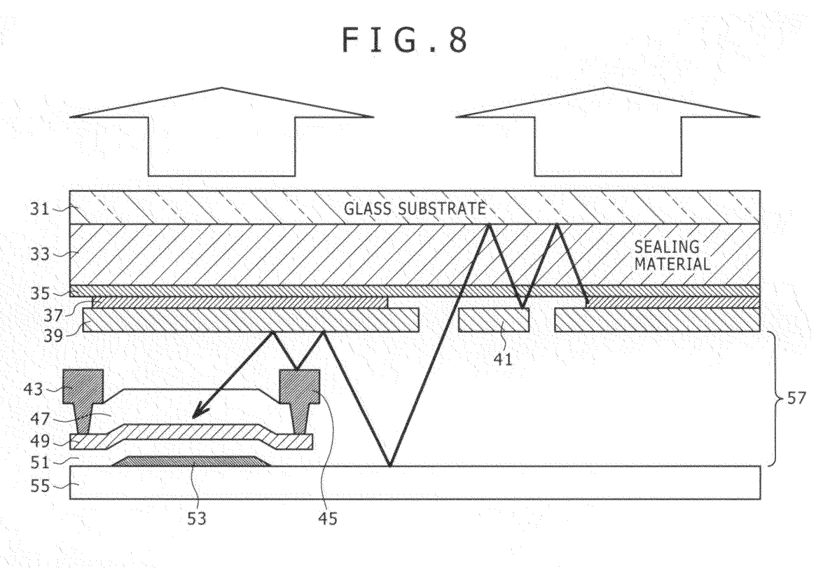

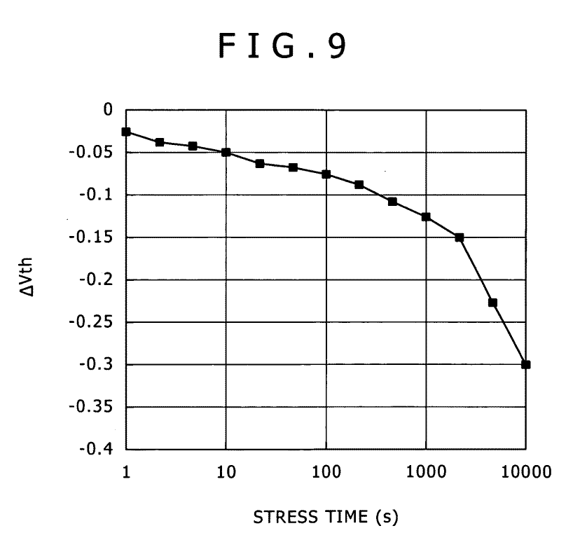

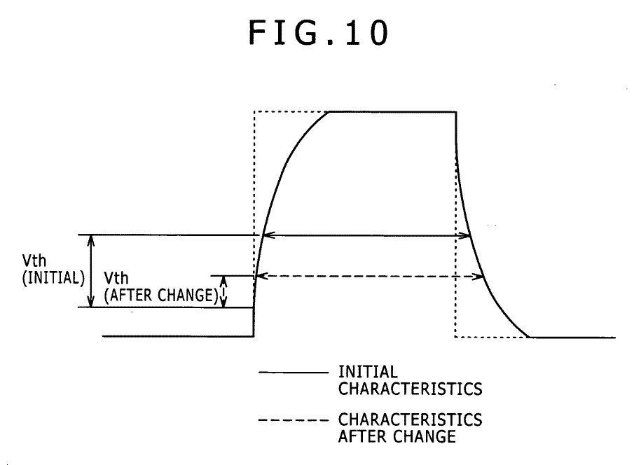

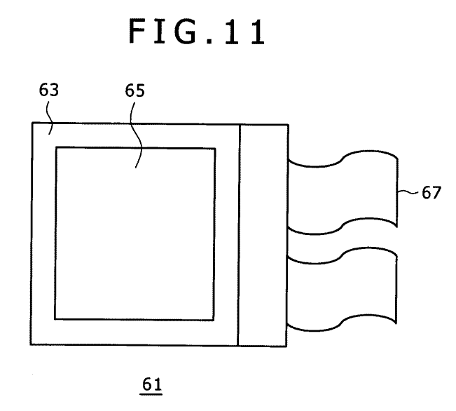

In this form example, the operation except for the operation in the mobility correction period is the same as the above-described drive operation of FIGS. 4A to 4E. Part of the light beam emitted from the respective sub-pixels 11 toward the panel surface remains as internal scattered light inside the glass substrate 31, and part of the internal scattered light enters the channel region of the sampling transistor T1 of adjacent another pixel circuit.

However, in this form example, the sampling transistors T1 of the respective pixel circuits are so arranged as to satisfy the conditions shown in FIG. 16. This suppresses the light amount of internal scattered light incident on the channel region of the sampling transistor T1 to an allowable level in practical use (level that permits the influence of the internal scattered light to be ignored in practical use).

Thus, change in the threshold voltage Vth of the sampling transistor T1 is suppressed and the optimum state of the mobility correction time is maintained.

In addition, higher effect of the avoidance of internal scattered light can be expected in the combination with the drive system including the mobility correction operation proposed in this form example.

As described above, in this form example, the supply voltage pulse WSP has a waveform in which the potential decreases in two stages after the elapse of a certain time from the start of the mobility correction so that the mobility correction time may be automatically optimized depending on the magnitude of the signal potential Vsig.

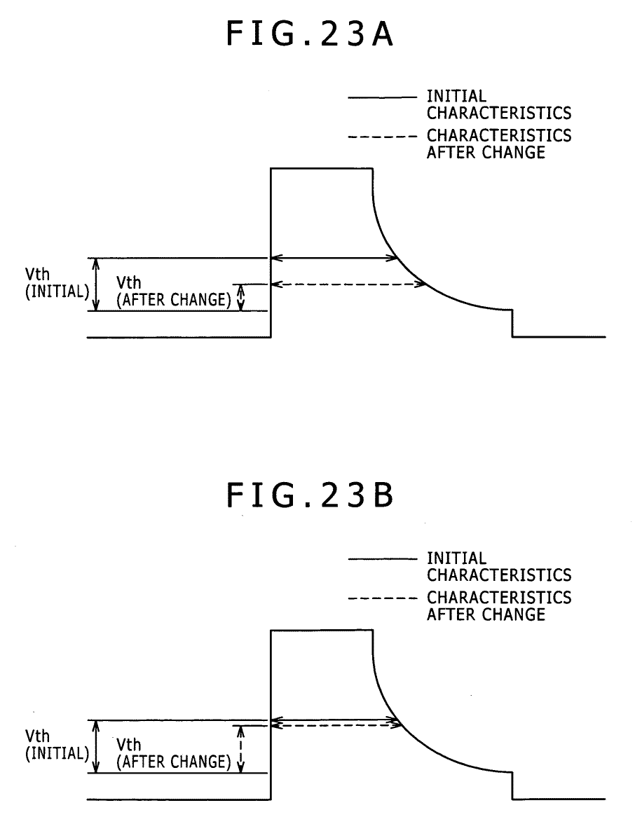

Therefore, if change in the threshold voltage Vth is large as shown in FIG. 23A, the mobility correction time greatly changes. In particular, in the case of the signal potential Vsig whose optimum mobility correction time corresponds to the region in which the potential sharply decreases, of the supply voltage pulse WSP, the decrease in the threshold voltage Vth greatly changes the on-time of the sampling transistor T1. This problem is specific to the drive system in which the potential of the supply voltage pulse WSP in the mobility correction time is distorted and decreased in two stages.

However, in this form example, change in the threshold voltage Vth can be minimized through avoidance of internal scattered light. Thus, as shown in FIG. 23B, it is possible to prevent the actual mobility correction time from greatly changing from the optimum mobility correction time for the signal potential Vsig.

As above, not merely that the avoidance of internal scattered light can contribute to stabilization of the operating point of the mobility correction time even by itself, but also higher effect thereof can be achieved when it is combined with the technique for optimizing the mobility correction time length.

### (C) Other Form Examples

### (C-1) Other Layout Examples of Sampling Transistors T1

In the above-described form example, the sampling transistors T1 for driving the R pixel and the G pixel are the same as the sampling transistor T1 for driving the B pixel in the position in the vertical direction in the pixel area.

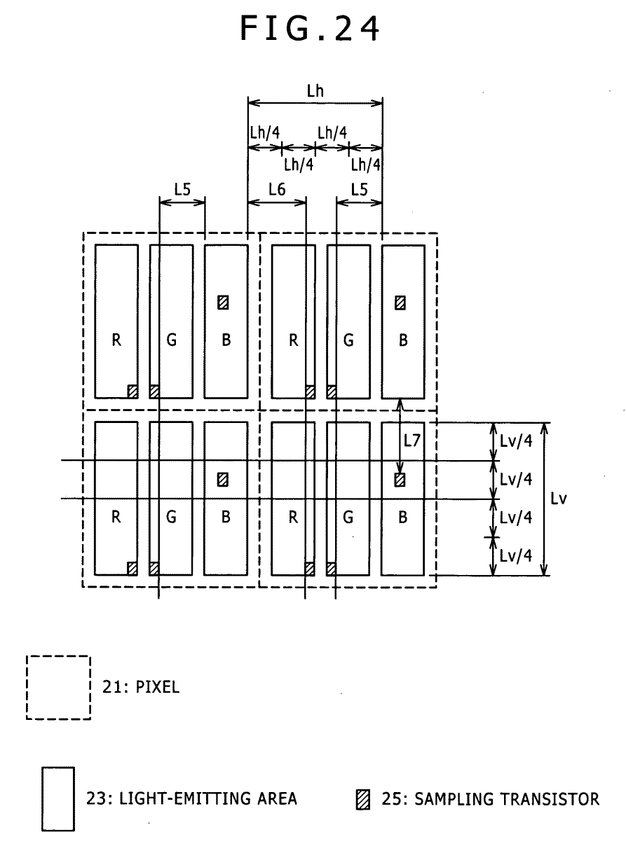

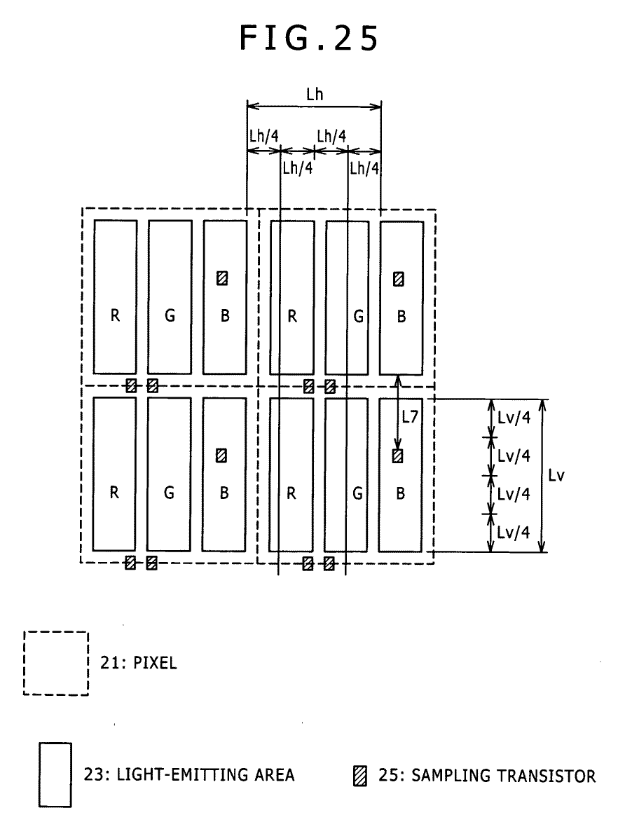

However, the position of the sampling transistor T1 in the vertical direction in the pixel area does not necessarily need to be the same for all of the emission colors. For example, as shown in FIGS. 24 and 25, the R pixel and the G pixel may be set different from the B pixel in the position of the sampling transistor T1 in the vertical direction.

In the example of FIG. 24, the sampling transistors T1 of the R pixel and the G pixel are disposed at the lowermost end of the light-emitting area. In the example of FIG. 25, the sampling transistors T1 of the R pixel and the G pixel are disposed at the boundary with the adjacent pixel area.

In addition, the sampling transistors T1 of the R pixel and the G pixel may be disposed at the lowermost end of the pixel area (outside the light-emitting area). Naturally, it is also possible to dispose the respective sampling transistors T1 at the upper end side of the light-emitting area or the pixel area. This is because the position in the vertical direction has no influence on the input of internal scattered light as long as the distance along the horizontal direction is the smallest as the distance between the B pixel and the adjacent pixel.

Furthermore, the R pixel does not necessarily need to be the same as the G pixel in the position of the sampling transistor T1 in the vertical direction in the pixel area although they are the same in the examples of FIGS. 24 and 25. That is, the position of the sampling transistor T1 in the pixel area may be changed on a color-by-color basis. In addition, the positions (the positions in the vertical direction and the horizontal direction) of the sampling transistors T1 of the same emission color may be different from each other depending on the positions thereof in the screen.

### (C-2) Other Pixel Structures

In the above-described form example, one pixel as a white unit is formed of an aggregation of three sub-pixels (R pixel, G pixel, B pixel). Furthermore, in the form example, the arrangement of the emission colors is in the order of the R pixel, the G pixel, and the B pixel along the horizontal direction.

However, the pixel structure and the arrangement of the light-emitting areas of one pixel are not limited thereto. FIG. 26 shows an example in which one pixel is formed of an aggregation of four sub-pixels (white (W) pixel, R pixel, G pixel, B pixel). In this case, the positions of the sampling transistors T1 are defined based on the group of the W pixel and the B pixel and the group of the R pixel and the G pixel.

This is because the light beam output from the W pixel contains the wavelength components of all of red, green, and blue. Therefore, in the pixel structure of FIG. 26, internal scattered light output from the W pixel and the B pixel causes change in the threshold voltage Vth of the sampling transistors T1 in the adjacent pixels.

In the pixel structure of FIG. 26, the W pixels and the B pixels are disposed on the left, right, upper, and lower sides of each of the R pixels and the G pixels. Therefore, the sampling transistors T1 corresponding to the R pixel and the G pixel are disposed in the overlapping area between the area corresponding to the range of one fourth to three fourths of the horizontal distance Lh1 between the peripheral edges of other light-emitting areas that are adjacent along the horizontal direction and the area corresponding to the range of one fourth to three fourths of the vertical distance Lv1 between the peripheral edges of other light-emitting areas that are adjacent along the vertical direction.

### (C-3) Other Pixel Circuit Examples

In the above-described form example, the pixel circuit for driving the sub-pixel 11 includes two thin film transistors T1 and T2 and one hold capacitor Cs.

However, the embodiment of the present invention is irrelevant to the structure of the pixel circuit. Therefore, the structure of the pixel circuit and the drive method therefor may be any ones. For example, the pixel circuit may include three or more thin film transistors. Furthermore, in the above-described form example, the sampling transistor T1 has a bottom-gate structure. However, it may have a top-gate structure.

### (C-4) Other Panel Structures

In the above-described form example, the EL display panel has a top-emission structure.

However, the EL display panel may have a bottom-emission structure. The bottom-emission structure refers to a panel structure of the type in which light is output from the circuit substrate side.

### (C-5) Product Examples

### (a) Electronic Apparatus

In the above description for the embodiment of the present invention, an organic EL panel is employed as an application example. However, the above-described organic EL panel is also distributed in a commercial product form of being mounted in various kinds of electronic apparatus. Examples of products obtained by mounting the organic EL panel in electronic apparatus will be described below.

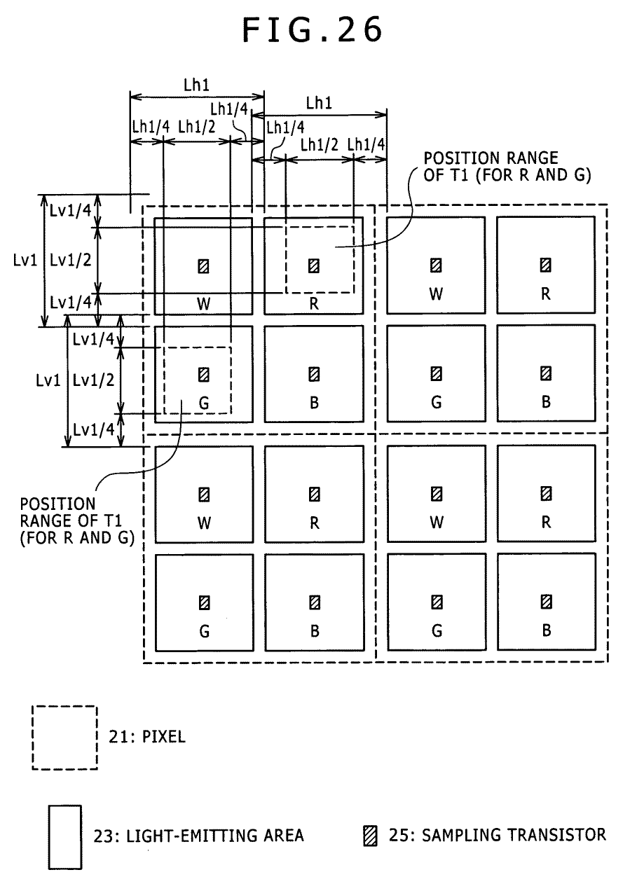

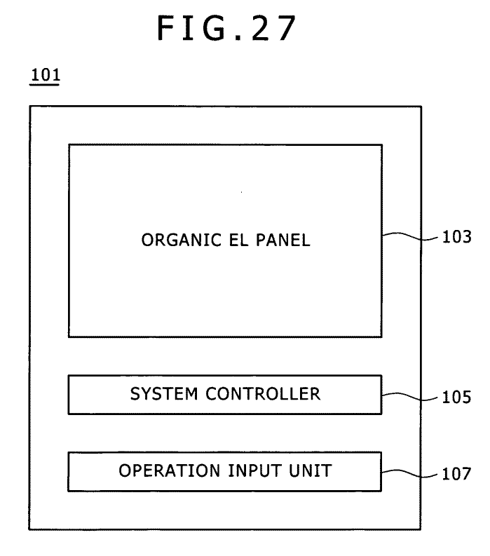

FIG. 27 shows a conceptual configuration example of electronic apparatus 101. The electronic apparatus 101 includes the above-described organic EL panel 103, a system controller 105, and an operation input unit 107. The processing executed by the system controller 105 differs depending on the commercial product form of the electronic apparatus 101. The operation input unit 107 is a device that accepts operation inputs to the system controller 105. As the operation input unit 107, e.g. a mechanical interface such as a switch and a button or a graphic interface is used.

The electronic apparatus 101 is not limited to apparatus of a specific field as long as it has a function to display an image and video produced therein or input from the external.

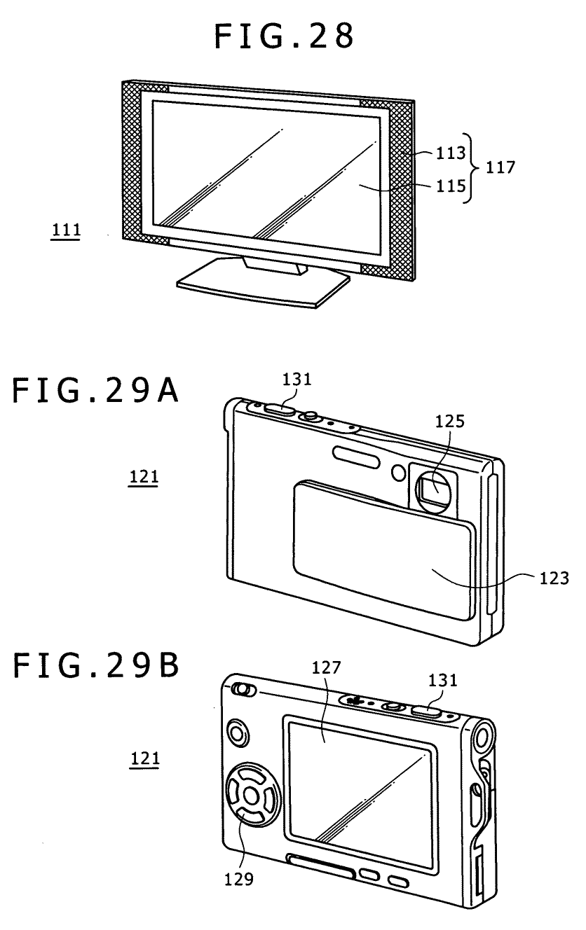

FIG. 28 is an appearance example of a television receiver as an example of the electronic apparatus. On the front face of the case of a television receiver 111, a display screen 117 composed of a front panel 113, a filter glass 115, and so on is disposed. The display screen 117 corresponds to the organic EL panel described for the form example.

Furthermore, e.g. a digital camera is available as this kind of electronic apparatus 101. FIGS. 29A and 29B show appearance examples of a digital camera 121. FIG. 29A shows an appearance example of the front-face side (subject side), and FIG. 29B shows an appearance example of the back-face side (photographer side).

The digital camera 121 includes a protective cover 123, an imaging lens unit 125, a display screen 127, a control switch 129, and a shutter button 131. The display screen 127 corresponds to the organic EL panel described for the form example.

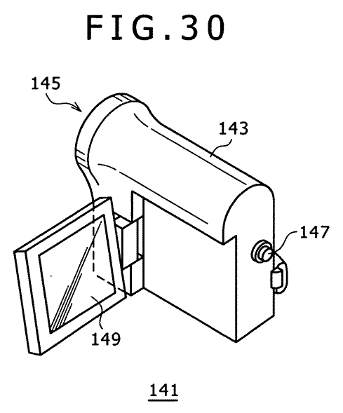

Furthermore, e.g. a video camera is also available as this kind of electronic apparatus 101. FIG. 30 shows an appearance example of a video camera 141.

The video camera 141 includes an imaging lens 145 that is disposed on the front side of a main body 143 and used to capture an image of a subject, a start/stop switch 147 for imaging, and a display screen 149. The display screen 149 corresponds to the organic EL panel described for the form example.

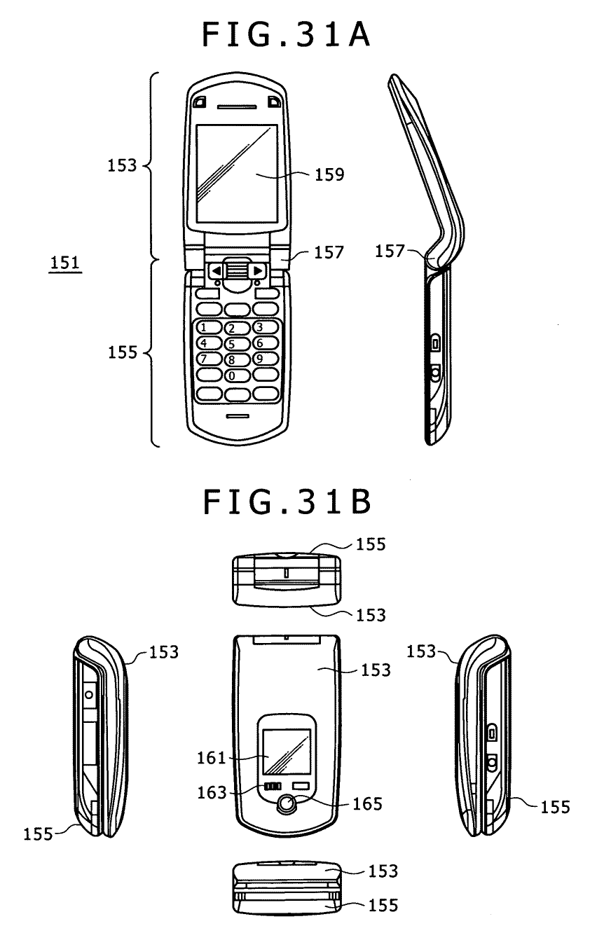

Furthermore, e.g. a portable terminal device is also available as this kind of electronic apparatus 101. FIGS. 31A and 31B are appearance examples of a cellular phone 151 as the portable terminal device. The cellular phone 151 shown in FIGS. 31A and 31B is a foldable type. FIG. 31A shows an appearance example of the opened state, and FIG. 31B shows an appearance example of the closed state.

The cellular phone 151 includes an upper case 153, a lower case 155, a connection (hinge, in this example) 157, a display screen 159, an auxiliary display screen 161, a picture light 163, and an imaging lens 165. The display screen 159 and the auxiliary display screen 161 correspond to the organic EL panel described for the form example.

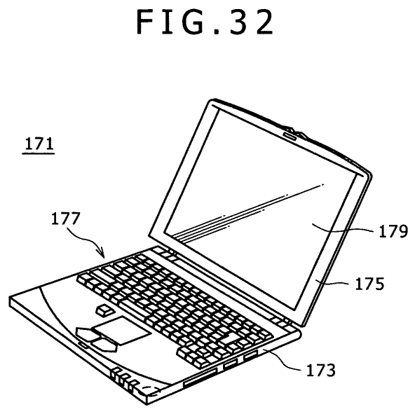

Furthermore, e.g. a computer is also available as this kind of electronic apparatus 101. FIG. 32 shows an appearance example of a notebook computer 171.

The notebook computer 171 includes a lower case 173, an upper case 175, a keyboard 177, and a display screen 179. The display screen 179 corresponds to the organic EL panel described for the form example.

Besides the above-described devices, an audio reproduction device, a game machine, an electronic book, an electronic dictionary, and so on are also available as the electronic apparatus 101.

### (C-6) Other Display Device Examples

In the above-described form example, the embodiment of the present invention is applied to an organic EL panel.

However, the above-described drive technique can also be applied to other display devices. For example, the drive technique can also be applied to a display device including arranged LEDs and other display devices in which light-emitting elements having a diode structure are arranged on the screen. For example, the embodiment of the present invention can also be applied to an inorganic EL panel.

### (C-7) Others

Various modifications might be incorporated into the above-described form examples without departing from the scope of the present invention. In addition, various modifications and applications that are created or combined based on the description of the present specification are also possible.

It should be understood by those skilled in the art that various modifications, combinations, sub-combinations and alterations may occur depending on design requirements and other factor in so far as they are within the scope of the appended claims or the equivalents thereof.

What is claimed is:

1. An electroluminescence display panel including pixel circuits corresponding to an active-matrix drive system, the electroluminescence display panel comprising
a structure configured to include first light-emitting areas corresponding to an emission color that is strongest in a characteristic of changing a threshold voltage of a thin film transistor and second light-emitting areas that correspond to another emission color and are each disposed between the first light-emitting areas, wherein
a sampling transistor in each of the pixel circuits for driving the second light-emitting areas is disposed in an area corresponding to a range of one fourth to three fourths of a length from a peripheral edge of one of two first light-emitting areas that are adjacent to each other with intermediary of the second light-emitting area of the sampling transistor to a peripheral edge of the other of the two first light-emitting areas.

2. The electroluminescence display panel according to claim 1, wherein
if the first light-emitting areas are adjacent to each other in the panel, a sampling transistor in each of the pixel circuits for driving the first light-emitting areas is disposed in an area corresponding to a range of one fourth to three fourths of a length of the first light-emitting area of the sampling transistor along a direction along which the first light-emitting areas are adjacent to each other.

3. The electroluminescence display panel according to claim 1, wherein
the first light-emitting area is a light-emitting area corresponding to blue.

4. An electronic apparatus comprising:
an electroluminescence display panel configured to include pixel circuits corresponding to an active-matrix drive system and have a structure that includes first light-emitting areas corresponding to an emission color that is strongest in a characteristic of changing a threshold voltage of a thin film transistor included in the pixel circuit and second light-emitting areas that correspond to another emission color and are each disposed between the first light-emitting areas, a sampling transistor in each of the pixel circuits for driving the second light-emitting areas being disposed in an area corresponding to a range of one fourth to three fourths of a length from a peripheral edge of one of two first light-emitting areas that are adjacent to each other with intermediary of the second light-emitting area to a peripheral edge of the other of the two first light-emitting areas;
a system controller configured to control operation of an entire system; and
an operation input unit configured to accept an operation input to the system controller.
